(19) United States
(12) Patent Application Publication
(10) Pub. No.: US 2024/0321681 A1
(43) Pub. Date: Sep. 26, 2024

(54) HEAT DISSIPATION STRUCTURE AND SEMICONDUCTOR PACKAGE INCLUDING THE SAME

(71) Applicant: Samsung Electronics Co., Ltd., Suwon-si (KR)

(72) Inventors: Sunggu Kang, Suwon-si (KR); Jaechoon Kim, Suwon-si (KR); Sungho Mun, Suwon si (KR); Hwanjoo Park, Suwon-si (KR)

(21) Appl. No.: 18/505,670

(22) Filed: Nov. 9, 2023

(30) Foreign Application Priority Data
Mar. 24, 2023 (KR) 10-2023-0039171
Apr. 7, 2023 (KR) 10-2023-0046198

(51) Int. Cl. H01L 23/46; H05K 7/20

(52) U.S. Cl. CPC H01L 23/46; H05K 7/20327

(57) ABSTRACT

Provided is a semiconductor package including a substrate, a first semiconductor device on the substrate, and a heat dissipation structure on the first semiconductor device including a heat dissipation chamber configured to provide an internal space in which a working fluid moves, and a plurality of first isolation walls arranged in the heat dissipation chamber to define a first center channel and a plurality of first vapor channels communicating with each other via the first center channel, wherein each of the plurality of first isolation walls vertically overlaps the first semiconductor device, the first center channel vertically overlaps the first semiconductor device, and each of the plurality of first vapor channels extends from the first center channel in a lateral direction.

### CROSS-REFERENCE TO RELATED APPLICATION

This application is based on and claims priority under 35 U.S.C. § 119 to Korean Patent Application Nos. 10-2023-0039171, filed on Mar. 24, 2023, and 10-2023-0046198, filed on Apr. 7, 2023 in the Korean Intellectual Property office, the disclosures of which are incorporated by reference herein in their entirety.

### BACKGROUND

Aspects of the inventive concept relate to a heat dissipation structure and a semiconductor package including the heat dissipation structure.

Recently, electronic products include various semiconductor devices packaged in one semiconductor package, and the various semiconductor devices are electrically connected to each other to operate as a single system. However, excessive heat may be generated when semiconductor devices operate, and thus, the performance of the semiconductor package may degrade due to such excessive heat.

### SUMMARY

Aspects of the inventive concept provide a heat dissipation structure having improved heat dissipation characteristics.

Aspects of the inventive concept provide a semiconductor package having improved heat dissipation characteristics.

According to an aspect of the inventive concept, a semiconductor package includes a substrate, a first semiconductor device on the substrate, and a heat dissipation structure on the first semiconductor device including a heat dissipation chamber configured to provide an internal space in which a working fluid moves, and a plurality of first isolation walls arranged in the heat dissipation chamber to define a first center channel and a plurality of first vapor channels communicating with each other via the first center channel, wherein each of the plurality of first isolation walls vertically overlaps the first semiconductor device, the first center channel vertically overlaps the first semiconductor device, and each of the plurality of first vapor channels extends from the first center channel in a lateral direction.

According to another aspect of the inventive concept, a semiconductor package includes a package substrate, an interposer substrate on the package substrate, a plurality of semiconductor devices mounted on the interposer substrate and apart from each other, and a heat dissipation structure arranged on the plurality of semiconductor devices. The heat dissipation structure includes a heat dissipation chamber including a lower wall, an upper wall, and sidewalls, and configured to provide an internal space in which a working fluid moves, a plurality of first isolation walls arranged in the heat dissipation chamber to form a first center channel and a plurality of first vapor channels communicating with each other via the first center channel and extending radially from the first center channel, and a plurality of micro-protruding structures arranged on an external surface of the heat dissipation chamber, wherein the first center channel vertically overlaps a first semiconductor device of the plurality of semiconductor devices, and each of the plurality of first isolation walls continuously extends horizontally from a first end thereof on the first semiconductor device to a second end thereof connected to any one of the sidewalls of the heat dissipation chamber.

According to another aspect of the inventive concept, a heat dissipation structure includes a heat dissipation chamber including a lower wall in contact with a heat source, an upper wall on the lower wall, and sidewalls extending between the lower wall and the upper wall, and configured to provide an internal space in which a working fluid moves, and a plurality of first isolation walls extending horizontally and arranged in the heat dissipation chamber to form a first center channel and a plurality of first vapor channels communicating with each other via the first center channel, wherein the plurality of first vapor channels radially extend from the first center channel.

### BRIEF DESCRIPTION OF THE DRAWINGS

Embodiments will be more clearly understood from the following detailed description taken in conjunction with the accompanying drawings in which:

FIG. 1 is a plan layout diagram of a semiconductor package according to an embodiment;

FIG. 2 is a cross-sectional view of a semiconductor package taken along line II-II′ in FIG. 1;

FIG. 3 is a cross-sectional view of a heat dissipation structure taken along line III-III′ in FIG. 1;

FIG. 4 is a plan layout diagram of a semiconductor package according to an embodiment;

FIG. 5 is a cross-sectional view of a semiconductor package according to an embodiment;

FIG. 6 is a plan layout diagram of a semiconductor package according to an embodiment;

FIG. 7 is a cross-sectional view of a semiconductor package taken along line VII-VII′ in FIG. 6;

FIG. 8 is a cross-sectional view of a semiconductor package according to an embodiment; and

FIGS. 9A and 9B are cross-sectional views illustrating a method of manufacturing a semiconductor package, according to embodiments.

### DETAILED DESCRIPTION

Hereinafter, embodiments of the inventive concept are described in detail with reference to the accompanying drawings. Identical reference numerals are used for the same constituent elements in the drawings, and duplicate descriptions thereof are omitted.

In the present disclosure, a vertical direction may be defined as a Z direction, and a horizontal direction may be defined as a direction perpendicular to the Z direction. A first horizontal direction and a second horizontal direction may be defined as directions crossing each other. A first horizontal direction may be referred to as an X direction, and a second horizontal direction may be referred to as a Y direction. The X direction and Y direction may be perpendicular to each other. A width of a component may be referred to as a length in the horizontal direction of the component, a vertical length, or height, of a component may be referred to as a length in the vertical direction of the component, and a plan area of a component may be referred to as the area occupied by the component on an XY plane.

In describing the various embodiments, when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element (or using any form of the word “contact”), there are no intervening elements present at the point of contact. Other words used to describe the relationship between elements should be interpreted in a like fashion (e.g., “between” versus “directly between,” “adjacent” versus “directly adjacent,” etc.).

Terms such as “same,” “equal,” “planar,” “coplanar,” “parallel,” and “perpendicular,” as used herein encompass identicality or near identicality including variations that may occur, for example, due to manufacturing processes. The term “substantially” may be used herein to emphasize this meaning, unless the context or other statements indicate otherwise.

Terms such as “about” or “approximately” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0%-5% deviation around 0.1 and a 0% to 5% deviation around 1, especially if such deviation maintains the same effect as the listed range.

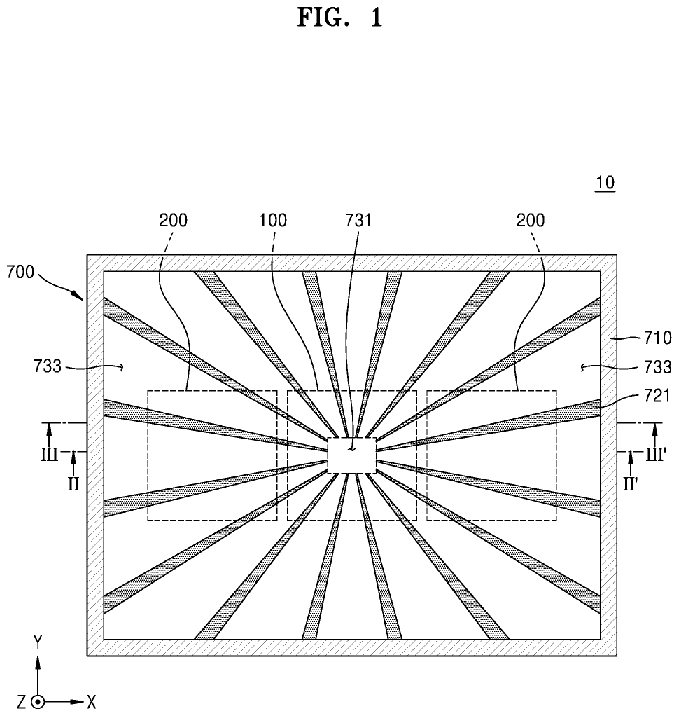

FIG. 1 is a plan layout diagram of a semiconductor package 10 according to an embodiment.

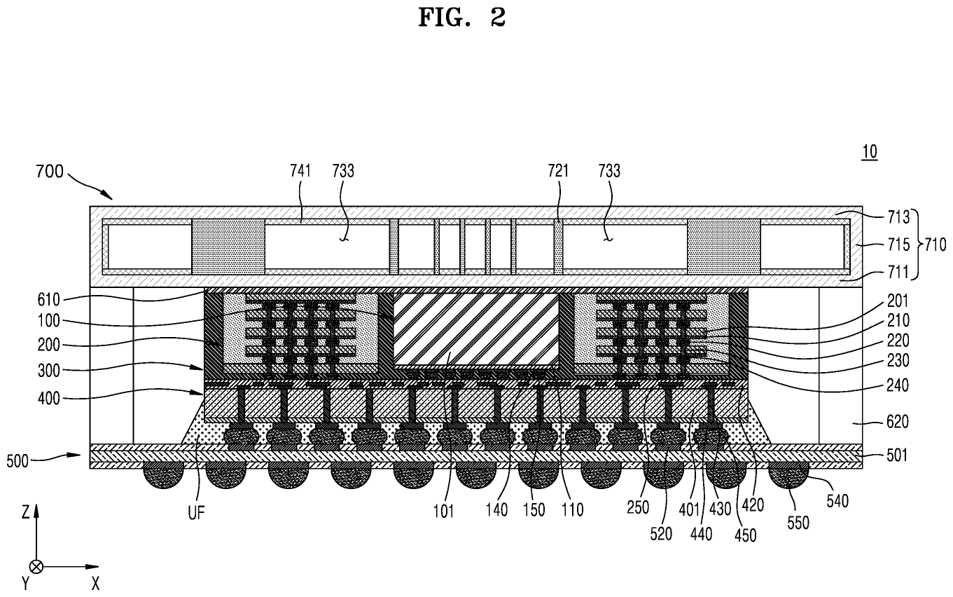

FIG. 2 is a cross-sectional view of the semiconductor package 10 taken along line II-II′ in FIG. 1.

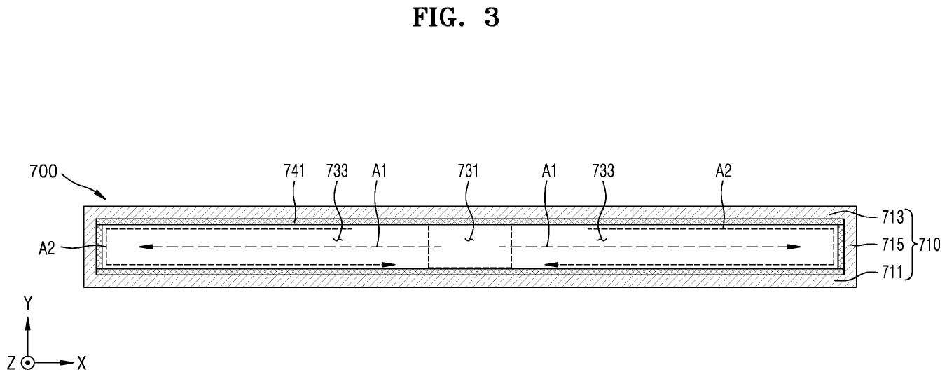

FIG. 3 is a cross-sectional view of a heat dissipation structure 700 taken along line III-III′ in FIG. 1.

Referring to FIGS. 1 through 3, the semiconductor package 10 may include a first semiconductor device 100, a second semiconductor device 200, a molding layer 300, an interposer substrate 400, a package substrate 500, and the heat dissipation structure 700.

The semiconductor package 10 may include the first semiconductor device 100 and the second semiconductor device 200, which perform different functions. The semiconductor package 10 may include one or more first semiconductor devices 100 and one or more second semiconductor devices 200. The first and second semiconductor devices 100 and 200 may be arranged side by side in the first horizontal direction (that is, the X direction) and/or the second horizontal direction (that is, the Y direction). The first and second semiconductor devices 100 and 200 may be electrically connected to each other via the interposer substrate 400. For example, the second semiconductor device 200 may be arranged on each of a first side and a second, opposite side of one first semiconductor device 100. However, the number and arrangement of semiconductor devices illustrated in FIGS. 1 and 2 are examples, and the number and arrangement of semiconductor devices may vary as desired. The first semiconductor device 100 may be a semiconductor chip or chip stack, or a semiconductor package including one or more semiconductor chips. Similarly, the second semiconductor device 200 may be a semiconductor chip or chip stack, or a semiconductor package including one or more semiconductor chips.

In some embodiments, the power consumption of the first semiconductor device 100 may be greater than the power consumption of the second semiconductor device 200, and the heat amount generated during the operation of the first semiconductor device 100 may be greater than the heat amount generated during the operation of the second semiconductor device 200.

The first semiconductor device 100 may be or may include a logic chip. The logic chip may include a plurality of logic devices (not illustrated) therein. A logic device may mean, for example, a device capable of performing various signal processing operations and including logic circuits, such as an AND gate, an OR gate, a NOT gate, and a flip-flop. In some embodiments, the logic device may include a device performing various signal processing operations, such as analog signal processing, analog-to-digital (A/D) conversion, and controlling.

In some embodiments, the first semiconductor device 100 may be implemented as a microprocessor, a graphics processor, a signal processor, a network processor, a chipset, an audio codec, a video codec, an application processor, a system-on-chip, etc.

The second semiconductor device 200 may be or may include a memory chip, for example, a volatile memory chip and/or a non-volatile memory chip. The volatile memory chip may be or may include, for example, dynamic random access memory (RAM) (DRAM), static RAM (SRAM), or thyristor RAM (TRAM). The non-volatile memory chip may include, for example, flash memory, magnetic RAM (MRAM), spin-transfer torque MRAM (STT-MRAM), ferroelectric RAM (FRAM), phase change RAM (PRAM), or resistive RAM (RRAM).

In some embodiments, the second semiconductor device 200 may be or may include a memory chiplet including a plurality of memory chips capable of merging data with each other. In addition, the second semiconductor device 200 may be or may include a high bandwidth memory (HBM) chip.

Examples of each component constituting the first and second semiconductor devices 100 and 200 are described in detail below.

The first semiconductor device 100 may include a first semiconductor substrate 101, a first semiconductor wiring layer 110, a plurality of first connection pads 140, and a plurality of first connection members 150.

The first semiconductor device 100 may be configured to include a single slice of semiconductor material, e.g., from a semiconductor wafer, and the single slice may include the first semiconductor substrate 101. The first semiconductor substrate 101 may include a die from a wafer, and may include an active surface and an inactive surface facing away from each other. In this case, the inactive surface of the first semiconductor substrate 101 may be an upper surface of the first semiconductor device 100 exposed to the molding layer 300. In one embodiment, the upper surface of the first semiconductor device 100 may be on a plane perpendicular to the vertical direction (for example, the Z direction).

The first semiconductor substrate 101 may be formed of or may include, for example, a silicon (Si) wafer including crystalline Si, polycrystalline Si, or amorphous Si. Alternatively, the first semiconductor substrate 101 may be formed of or may include a semiconductor, such as germanium (Ge), or a compound semiconductor, such as silicon carbide (SiC), gallium arsenide (GaAs), indium arsenide (InAs), and indium phosphide (InP).

On the other hand, the semiconductor substrate 101 may have a silicon on insulator (SOI) structure. For example, the first semiconductor substrate 101 may include a buried oxide (BOX) layer. In some embodiments, the first semiconductor substrate 101 may include a conductive region, for example, a well doped with impurities, or a structure doped with impurities. In addition, the first semiconductor substrate 101 may have various device isolation structures such as a shallow trench isolation (STI) structure.

The first semiconductor wiring layer 110 may be arranged on the active surface of the first semiconductor substrate 101, and may be electrically connected to the first connection pads 140 on the first semiconductor wiring layer 110. The first semiconductor wiring layer 110 may be electrically connected to the first connection members 150 via the first connection pads 140. The first connection pads 140 may be or may include at least one of, for example, aluminum (Al), copper (Cu), nickel (Ni), tungsten (W), platinum (PT), and gold (Au).

The first connection members 150 may be arranged to electrically connect the first semiconductor device 100 to the interposer substrate 400. Each connection member of the first connection members 150 may include a solder (e.g., solder ball) attached to the first connection pad 140. The first connection members 150 may be described as semiconductor device connection terminals. The material constituting each solder ball may include at least one of Au, Ag, Cu, tin (Sn), and Al. In some embodiments, the solder balls may be connected to the first connection pads 140 by using any one of a thermo-compression connection method and an ultrasonic connection method, and may also be connected to the first connection pads 140 by using the thermo-compression connection method.

The first semiconductor device 100 may receive at least one of a control signal, a power signal, and a ground signal for an operation thereof from the outside via the first connection members 150, receive a data signal to be input thereto from the outside, or may provide a data signal thereof to the outside.

The second semiconductor device 200 may include a second semiconductor substrate 201, a second semiconductor wiring layer 210, second upper connection pads 220, second through electrodes 230, second lower connection pads 240, and a second connection members 250. Ordinal numbers such as “first,” “second,” “third,” etc. may be used simply as labels of certain elements, steps, etc., to distinguish such elements, steps, etc. from one another. Terms that are not described using “first,” “second,” etc., in the specification, may still be referred to as “first” or “second” in a claim. In addition, a term that is referenced with a particular ordinal number (e.g., “first” in a particular claim) may be described elsewhere with a different ordinal number (e.g., “second” in the specification or another claim).

Each second semiconductor device 200 may include a plurality of slices, and each of the plurality of slices may include the second semiconductor substrate 201. Each slice may be a semiconductor chip. A plurality of second semiconductor substrates 201 may constitute a chip stack and may be stacked in the vertical direction (for example, the Z direction). The plurality of second semiconductor substrates 201 may be substantially the same as each other. Therefore, the second semiconductor device 200 may have a stacked structure, in which each of the plurality of slices operates as a memory chip, and data may be merged with each other.

Each of the plurality of second semiconductor substrates 201 may have an active surface and an inactive surface facing away from each other. In this case, the inactive surface of the second semiconductor substrate 201, that is uppermost among the plurality of second semiconductor substrates 201, may be an upper surface of the second semiconductor device 200 exposed to the molding layer 300. The remaining second semiconductor substrates 201 except for the second semiconductor substrate 201 at the uppermost portion of the plurality of second semiconductor substrates 201 may include the second through electrode 230. The second through electrode 230 may include, for example, a through silicon via (TSV, more generally described as a through substrate via).

The second upper connection pads 220 may be connected to an upper side of the second through electrodes 230, and the second lower connection pads 240 may be connected to a lower side of the second through electrodes 230. In addition, the second lower connection pads 240 may be electrically connected to the second semiconductor wiring layer 210 on the active surface of the second semiconductor substrate 201. The second semiconductor wiring layer 210 may be electrically connected to the second connection members 250 via the second lower connection pads 240.

The second connection member 250 in contact with the second semiconductor substrate 201, that is lowermost among the plurality of second semiconductor substrates 201, may electrically connect between the second semiconductor device 200 and the interposer substrate 400. The second connection member 250 may include a solder to be attached to the second lower connection pad 240.

The second semiconductor device 200 may receive at least one of a control signal, a power signal, and a ground signal for an operation thereof from the outside via the second connection members 250, or receive a data signal to be input thereto from the outside, or may provide a data signal thereof to the outside.

The molding layer 300 may be formed to surround the first and second semiconductor devices 100 and 200. The molding layer 300 may extend along the side surfaces and bottom surfaces of each of the first and second semiconductor devices 100 and 200, and may cover the side surfaces and bottom surfaces of each of the first and second semiconductor devices 100 and 200. In this case, the molding layer 300 may not cover the upper surface of the first semiconductor device 100 and the upper surface of the second semiconductor device 200. In some embodiments, an upper surface of the molding layer 300 may be coplanar with the upper surface of the first semiconductor device 100 and the upper surface of the second semiconductor device 200.

The molding layer 300 may protect the first and second semiconductor devices 100 and 200 from external influences, such as impact and contamination. To perform the protection operation, the molding layer 300 may be or may include an epoxy mold compound, or resin, etc. In addition, the molding layer 300 may be formed by using a process, such as compression molding, lamination, and screen printing.

The interposer substrate 400 may be arranged below the first and second semiconductor devices 100 and 200, and may electrically connect the first semiconductor device 100 to the second semiconductor device 200. In some embodiments, the interposer substrate 400 may include a silicon substrate 401, and may include a redistribution structure 420 arranged on the silicon substrate 401. In addition, the interposer substrate 400 may include through electrodes 430 electrically connected to the redistribution structure 420 and passing through the silicon substrate 401, connection pads 440 arranged below the silicon substrate 401 and electrically connected to the through electrodes 430, and an internal connection terminals 450 attached to the connection pads 440. The various pads, electrodes, and terminals described herein may be formed of conductive material, such as metal, in various example embodiments.

The package substrate 500 may be arranged under the interposer substrate 400. The package substrate 500 may be formed based on a printed circuit board, a wafer substrate, a ceramic substrate, a glass substrate, etc. In some embodiments, the package substrate 500 may include a printed circuit board. The package substrate 500 may include bump pads 540 arranged on a lower surface of a body unit 501 and external connection terminals 550 attached to the bump pads 540. The semiconductor package 10 may be electrically connected to a main board, a system board, or the like of an external electronic device on which the semiconductor package 10 is mounted by using the external connection terminals 550.

An underfill layer UF may be arranged between the interposer substrate 400 and the package substrate 500. The underfill layer UF may fill the gap between the interposer substrate 400 and the package substrate 500 and surround the internal connection terminals 450. The underfill layer UF may include or be, for example, epoxy resin. In some embodiments, a non-conductive film (NCF) may be formed instead of the underfill layer UF.

The heat dissipation structure 700 may be arranged over the first and second semiconductor devices 100 and 200, and may be thermally coupled to the first and second semiconductor devices 100 and 200. The heat dissipation structure 700 may be attached to the first and second semiconductor devices 100 and 200 by a thermally conductive adhesive layer 610 applied on the upper surfaces of the first and second semiconductor devices 100 and 200. The thermally conductive adhesive layer 610 may conformally extend along the upper surface of the first semiconductor device 100 and the upper surface of the second semiconductor device 200. The thermally conductive adhesive layer 610 may be thermally conductive and electrically non-conductive. The thermally conductive adhesive layer 610 may include a resin layer including various fillers. The thermally conductive adhesive layer 610 may include or be a thermal interface material (TIM) layer.

The heat dissipation structure 700 may be configured to be thermally coupled to the first and second semiconductor devices 100 and 200, and may be configured to cool the first and second semiconductor devices 100 and 200 in an immersion cooling method. The heat dissipation structure 700 may be configured to cool a heat source through a phase change of a working fluid. In the heat dissipation structure 700, the working fluid in a liquidous state evaporates through heat exchange with the heat source and phase changes into a gaseous state, and the working fluid in the gaseous state may condense through heat exchange with a cold wall in the heat dissipation structure 700 and phase change into a liquidous state. Through a phase change of the working fluid, heat of the heat source (for example, the first and second semiconductor devices 100 and 200) may be discharged to the outside. The working fluid may include a refrigerant configured to phase change in the operation temperature range of the semiconductor package 10. The working fluid may be or include, for example, water, ethylene glycol, silicone oil, mineral oil, liquid Teflon, or a mixture thereof.

The heat dissipation structure 700 may include a heat dissipation chamber 710 providing an internal space for the working fluid to flow, a plurality of first isolation walls 721 provided in the heat dissipation chamber 710, and a first wick structure 741 provided in the heat dissipation chamber 710.

The heat dissipation chamber 710 may include a lower wall 711, an upper wall 713 on the lower wall 711, and sidewalls 715 extending between the lower wall 711 and the upper wall 713. The lower wall 711 and the upper wall 713 may each have a flat plate shape, and may be parallel to each other. The lower wall 711 may be attached to the first and second semiconductor devices 100 and 200 via the thermally conductive adhesive layer 610.

The material of the heat dissipation chamber 710 may be or include a metal, such as Cu, Al, and stainless steel (SUS). The heat dissipation chamber 710 may be formed of a continuous, integrally-formed material, or may be formed of separate connected pieces.

A plan area of the heat dissipation chamber 710 may be greater than a plan area of the interposer substrate 400. The center portion of the heat dissipation chamber 710 may vertically overlap the interposer substrate 400, and the outer portion of the heat dissipation chamber 710 may protrude outward from the interposer substrate 400. The periphery portion of the heat dissipation chamber 710 may be supported by a support structure 620, also described as a support wall, attached to the periphery portion of the package substrate 500. The support structure 620 may be attached to the package substrate 500 by using an adhesive material layer. The material of the support structure 620 may be or include a metal, such as Cu, Al, and SUS. In some embodiments, the support structure 620 may be integrated with the heat dissipation chamber 710 into one body, and the support structure 620 and the heat dissipation chamber 710 may include the same material.

The plurality of first isolation walls 721 may be provided in the heat dissipation chamber 710 to improve the mechanical stability of the heat dissipation chamber 710. Each of the first isolation walls 721 may extend vertically from the lower wall 711 to the upper wall 713, and may be coupled to each of the lower wall 711 and the upper wall 713. Each of the first isolation walls 721 may continuously contact each of the lower wall 711 and the upper wall 713 in a lateral direction. In some embodiments, the plurality of first isolation walls 721 may be integrated with the heat dissipation chamber 710 into one body, and may include the same material as the material of the heat dissipation chamber 710. In some embodiments, the material of the plurality of first isolation walls 721 may be different from the material of the heat dissipation chamber 710. For example, the plurality of first isolation walls 721 may be formed of or may include one or more metals, such as Cu, Al, and SUS.

The plurality of first isolation walls 721 may respectively form a plurality of first vapor channels 733 in the heat dissipation chamber 710, and guide the flow of the working fluid in the heat dissipation chamber 710. The plurality of first isolation walls 721 may be apart from each other, and one first vapor channel 733 may be defined as a space between two adjacent first isolation walls 721. In some embodiments, the plurality of first isolation walls 721 may respectively define the plurality of first vapor channels 733 which communicate with a first center channel 731 via the first center channel 731. In a plan view, the plurality of first vapor channels 733 may radially extend around the first center channel 731.

The first center channel 731 may vertically overlap the heat source. In some embodiments, the first center channel 731 may vertically overlap the first semiconductor device 100, and each first vapor channel 733 may extend in the lateral direction from the first center channel 731 toward one of the sidewalls 715 of the heat dissipation chamber 710. The first center channel 731 may be continuously formed with one or more first vapor channels 733 to be devoid of solid material, and to allow for the flow of fluids such as liquid and gas therethrough.

In some embodiments, the horizontal width of each first vapor channel 733 may gradually increase toward a corresponding sidewall 715 thereto of the sidewalls 715 of the heat dissipation chamber 710. In some embodiments, the width of each of the first vapor channels 733 in the horizontal direction may be constant. The width of each first vapor channel 733 in the horizontal direction may be defined as a length measured in a direction perpendicular to an extension direction of the first vapor channel 733, wherein the extension direction is a direction along a line that bisects the first vapor channel in the horizontal direction, and the width is measured perpendicular to the line. In some embodiments, the width in the horizontal direction of each of the first vapor channels 733 may be between about 0.5 mm and about 10 mm. For example, in an embodiment in which the width increases, the minimum width of each first vapor channel 733 (e.g., at a first end adjacent to the first center channel 731) may be between about ⅓ to about 1/20 the maximum width (e.g., at a second end adjacent to the sidewalls 715). In this case, for each first vapor channel 733, the minimum width may be between about 0.5 mm and 3.5 mm, and the maximum width may be greater than the minimum width and be between about 1.5 mm and 10 mm. In some embodiments, the vertical length (e.g., height) of each of the first vapor channels 733 may be between about 0.5 mm and about 10 mm. Some of the first vapor channels 733 may have an irregular quadrilateral shape, some may have an irregular 5 or 6 sided polygon shape, and some may have a trapezoid shape.

To form the plurality of first vapor channels 733 radially extending in the heat dissipation chamber 710, each of the plurality of first isolation walls 721 may radially extend around a reference point (for example, one point in the first center channel 731). In a plan view, each first isolation wall 721 may extend continuously and linearly from one end (e.g., a first end) vertically overlapping with the first semiconductor device 100 to the other end (e.g., a second end opposite the first end) connected to one of the sidewalls 715 of the heat dissipation chamber 710. In a plan view, at least one of the plurality of first isolation walls 721 may extend across the upper surface of the second semiconductor device 200 in a lateral direction (e.g., to vertically overlap the second semiconductor device 200).

In some embodiments, the horizontal width of each first isolation wall 721 may gradually increase toward the sidewall 715 corresponding thereto of the sidewalls 715 of the heat dissipation chamber 710. In some embodiments, the width of each of the first isolation walls 721 in the horizontal direction may be constant. The width in the horizontal direction may be defined as a length measured in a direction perpendicular to the extension direction of the first isolation wall 721, wherein the extension direction is a direction along a line that bisects the first isolation wall in the horizontal direction, and the width is measured perpendicular to the line. In some embodiments, the width in the horizontal direction of each of the first isolation walls 721 may be between about 0.5 mm and about 10 mm. For example, where the width increases, the minimum width of each first isolation wall 721 (e.g., at a first end adjacent to the first center channel 731) may be between about ⅓ to about 1/20 the maximum width (e.g., at a second end adjacent to the sidewalls 715. In this case, for each first isolation wall 721, the minimum width may be between about 0.5 mm and 3.5 mm, and the maximum width may be greater than the minimum width and be between about 1.5 mm and 10 mm. In some embodiments, the vertical length (e.g., height) of each of the first isolation walls 721 may be between about 0.5 mm and about 10 mm. Each first isolation wall 721 may have an irregular quadrilateral shape.

In the heat dissipation structure 700, the lower wall 711 of the heat dissipation chamber 710 in thermal communication with the heat source (for example, the first and second semiconductor devices 100 and 200) may include an evaporator, in which the working fluid in a liquidous state evaporates, and the upper wall 713 and the sidewall 715 of the heat dissipation chamber 710 exposed to external air (that is, the air outside the heat dissipation structure 700) may form a condenser, in which the working fluid is condensed. When the lower wall 711 is heated by a heat source (that is, the first and second semiconductor devices 100 and 200), because the space adjacent to the lower wall 711 may have relatively high pressure, a pressure gradient may be formed in the heat dissipation chamber 710. Depending on the pressure gradient in the heat dissipation chamber 710, the working fluid in a gaseous state may flow from the lower wall 711 in a direction toward the upper wall 713, or from one region of the lower wall 711 overlapping the heat source in a direction toward the sidewall 715. The heat source may be cooled in the process of evaporating the working fluid in the liquidous state, and heat may be discharged to external air in the process of condensing the working fluid in the gaseous state.

In some embodiments, the first center channel 731 may overlap the first semiconductor device 100 having the highest consumed power among semiconductor devices included in the semiconductor package 10 or having the highest operation heat amount. In this case, in the heat dissipation chamber 710, the vaporized working fluid may diffuse along the plurality of first vapor channels 733 radially extending from the first center channel 731. In other words, like a vapor flow path A1 illustrated in FIG. 3, the vaporized working fluid may radially diffuse from the first center channel 731. According to embodiments, as the plurality of first vapor channels 733 radially extending around the first center channel 731 are formed in the heat dissipation chamber 710, the vaporized working fluid may diffuse generally evenly in the heat dissipation chamber 710, and heat exchange between the heat dissipation structure 700 and external air may be uniform as a whole.

The first wick structure 741 may extend along the inner wall surface of the heat dissipation chamber 710. The first wick structure 741 may be attached to at least one of a surface of the lower wall 711, a surface of the upper wall 713, and surfaces of the sidewalls 715. In some embodiments, the first wick structure 741 may be attached to all of the surface of the lower wall 711, the surface of the upper wall 713, and the surfaces of the sidewalls 715. In some embodiments, the first wick structure 741 may be attached only to the surface of the lower wall 711, the surface of the upper wall 713, and some of the surfaces of the sidewalls 715. For example, the first wick structure 741 may be formed on the surface of the lower wall 711, but the first wick structure 741 may not be formed on the surface of the upper wall 713 and the surfaces of the sidewalls 715. The first wick structure 741 may generate a capillary force for moving the working fluid in the liquidous state toward the heat source. The first wick structure 741 may have a structure for generating the capillary force, and may include, for example, a groove pattern. The first wick structure 741 may include or be formed of a metal or metal powder sintered body. For example, the first wick structure 741 may be or include Cu and Al. In the heat dissipation chamber 710, the working fluid in the liquid phase may move toward the heat source by gravity or the capillary force of the first wick structure 741. For example, like a flow path A2 illustrated in FIG. 3, the condensed working fluid may flow along the first wick structure 741 toward the first center channel 731 vertically overlapping the heat source.

According to embodiments of the inventive concept, because the heat dissipation structure 700 includes the plurality of first isolation walls 721 mechanically supporting the heat dissipation chamber 710, the heat dissipation structure 700 may prevent thermal damage such as thermal deformation and degradation of heat dissipation characteristics due to the thermal damage. As a result, the reliability and heat dissipation characteristics of the heat dissipation structure 700 may be improved, and the reliability and heat dissipation characteristics of the semiconductor package 10 including the heat dissipation structure 700 may be improved.

According to embodiments of the inventive concept, because the heat dissipation structure 700 includes the plurality of first vapor channels 733 radially diffused around the heat source therein, the uniformity of vapor diffusion in the heat dissipation structure 700 may be improved. Because the uniformity of vapor diffusion within the heat dissipation structure 700 is improved, the uniformity of heat exchange between the heat dissipation structure 700 and external air may be improved, and the total heat dissipation characteristics of the heat dissipation structure 700 may be improved. Accordingly, the heat dissipation structure 700 may have improved heat dissipation characteristics, and the heat dissipation characteristics and reliability of the semiconductor package 10 including the heat dissipation structure 700 may be improved.

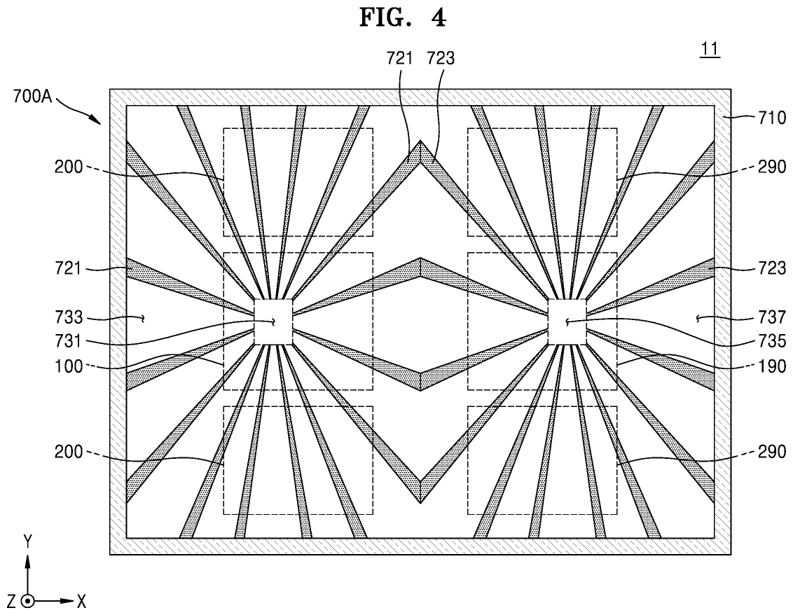

FIG. 4 is a plan layout diagram of a semiconductor package 11 according to an embodiment. Hereinafter, the semiconductor package 11 illustrated in FIG. 4 is described, focusing on the difference from the semiconductor package 10 described with reference to FIGS. 1 through 3.

Referring to FIG. 4, the semiconductor package 11 may include the first semiconductor device 100, second semiconductor devices 200 arranged on one side (e.g., a first side) and the other side (e.g., a second, opposite side) of the first semiconductor device 100, a third semiconductor device 190, and fourth semiconductor devices 290 arranged on one side (e.g., a first side) and the other side (e.g., a second, opposite side) of the third semiconductor device 190. The first semiconductor device 100 and the third semiconductor device 190 may be mounted on the interposer substrate (refer to 400 in FIG. 2) and apart from each other in the first horizontal direction (for example, the X direction). The second semiconductor devices 200 may be mounted on the interposer substrate 400, and apart from each other in the second horizontal direction (for example, the Y direction) with the first semiconductor device 100 therebetween. The fourth semiconductor devices 290 may be mounted on the interposer substrate 400, and apart from each other in the second horizontal direction (for example, the Y direction) with the first semiconductor device 100 therebetween. The first semiconductor device 100, the second semiconductor devices 200, the third semiconductor device 190, and the fourth semiconductor devices 290 may be electrically connected to each other via the interposer substrate 400, and may include logic chips and memory chips. In some embodiments, the first semiconductor device 100 and the third semiconductor device 190 may include logic chips. In some embodiments, the second semiconductor devices 200 and the fourth semiconductor devices 290 may include memory chips.

In the semiconductor package 11, a heat dissipation structure 700A may cover the first semiconductor device 100, the second semiconductor devices 200, the third semiconductor device 190, and the fourth semiconductor devices 290, and may be thermally coupled to the first semiconductor device 100, the second semiconductor devices 200, the third semiconductor device 190, and the fourth semiconductor devices 290.

The heat dissipation structure 700A may include the plurality of first isolation walls 721 and a plurality of second isolation walls 723. Similar to each first isolation wall 721, each second isolation wall 723 may extend from the lower wall (711 in FIG. 2) to the upper wall (713 in FIG. 2), and may continuously contact each of the lower wall 711 and the upper wall 713 in the lateral direction. The material of the second isolation wall 723 may be the same as the material of the first isolation wall 721, and the dimensions of the second isolation wall 723 may be similar or the same as the dimensions of the first isolation wall 721.

The plurality of second isolation walls 723 may form, in the heat dissipation chamber 710, a second center channel 735 and a plurality of second vapor channels 737 communicating with each other via the second center channel 735. The plurality of second isolation walls 723 may be apart from each other, and one second vapor channel 737 may be defined as a space between two adjacent second isolation walls 723. In a plan view, the plurality of second vapor channels 737 may radially extend around the second center channel 735. The first center channel 731 may vertically overlap the first semiconductor device 100, and the second center channel 735 may vertically overlap the third semiconductor device 190. Each second vapor channel 737 may extend in a lateral direction from the second center channel 735 toward any one of the sidewalls (715 in FIG. 2) of the heat dissipation chamber 710.

Each of the plurality of second isolation walls 723 may radially extend around a reference point (for example, a point in the second center channel 735). At least one of the plurality of second isolation walls 723 may extend across an upper surface of the fourth semiconductor device 290 in a lateral direction.

Each second isolation wall 723 of a first set of the second isolation walls 723 of the plurality of second isolation walls 723 may extend continuously and linearly from a first end, which vertically overlaps the third semiconductor device 190, to a second, opposite end, which is connected to any one of the sidewalls 715 of the heat dissipation chamber 710. Each second isolation wall 723 of a second set of the second isolation walls 723 of the plurality of second isolation walls 723 may be connected to a respective first isolation wall 721 of the first isolation walls 721 (e.g., to extend continuously and linearly from a first end, which vertically overlaps the third semiconductor device 190, to a second, opposite end, which is connected to the respective first isolation wall 721). At least one second vapor channel 737 of the plurality of second vapor channels 737 may communicate with the first vapor channel 733.

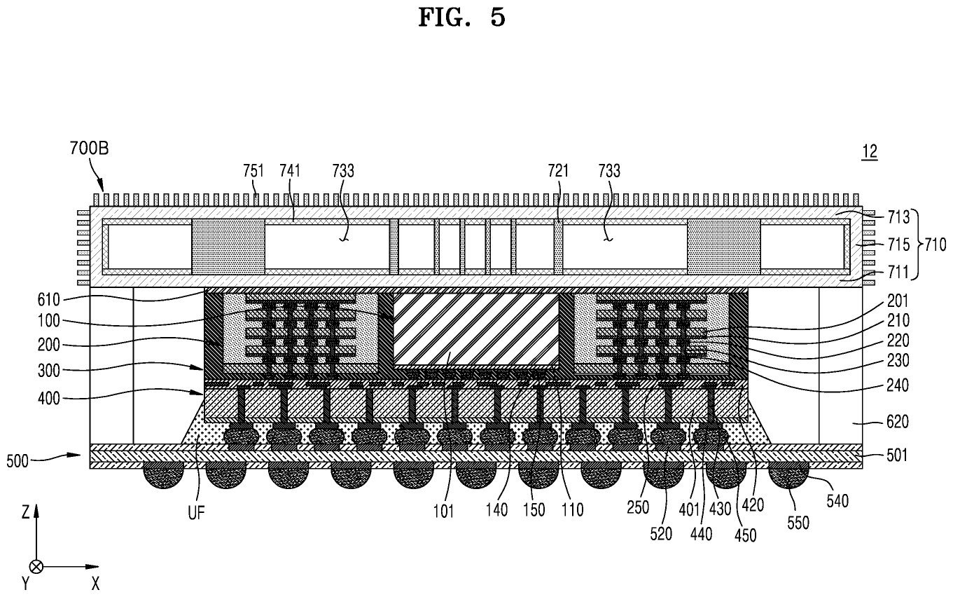

FIG. 5 is a cross-sectional view of a semiconductor package 12 according to an embodiment. Hereinafter, the semiconductor package 12 illustrated in FIG. 5 is described, focusing on the difference from the semiconductor package 10 described with reference to FIGS. 1 through 3.

Referring to FIG. 5, in the semiconductor package 12, a heat dissipation structure 700B may further include a plurality of micro-protruding structures 751 provided on the outer surface of the heat dissipation chamber 710. The plurality of micro-protruding structures 751 may improve the heat exchange efficiency between the heat dissipation structure 700B and external air, by increasing the heat exchange area between the heat dissipation structure 700B and external air. The plurality of micro-protruding structures 751 may be provided on the outer surface of the upper wall 713 and/or on the outer surface of each of the sidewalls 715. Each of the micro-protruding structures 751 may have a fin shape or a bump shape. In some embodiments, the micro-protruding structure 751 may be integrated with the heat dissipation chamber 710 into one body, and the material of the micro-protruding structure 751 may be the same as the material of the heat dissipation chamber 710. In some embodiments, the material of the micro-protruding structure 751 may be different from the material of the heat dissipation chamber 710.

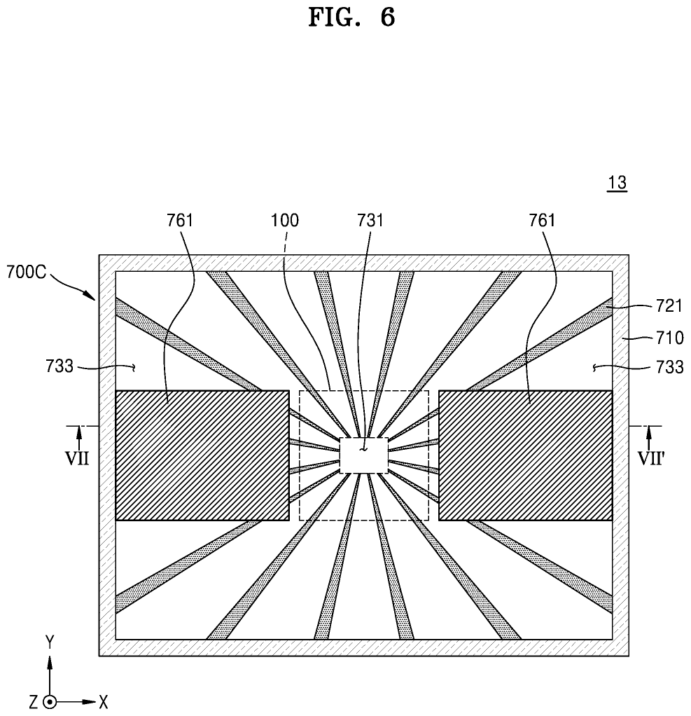

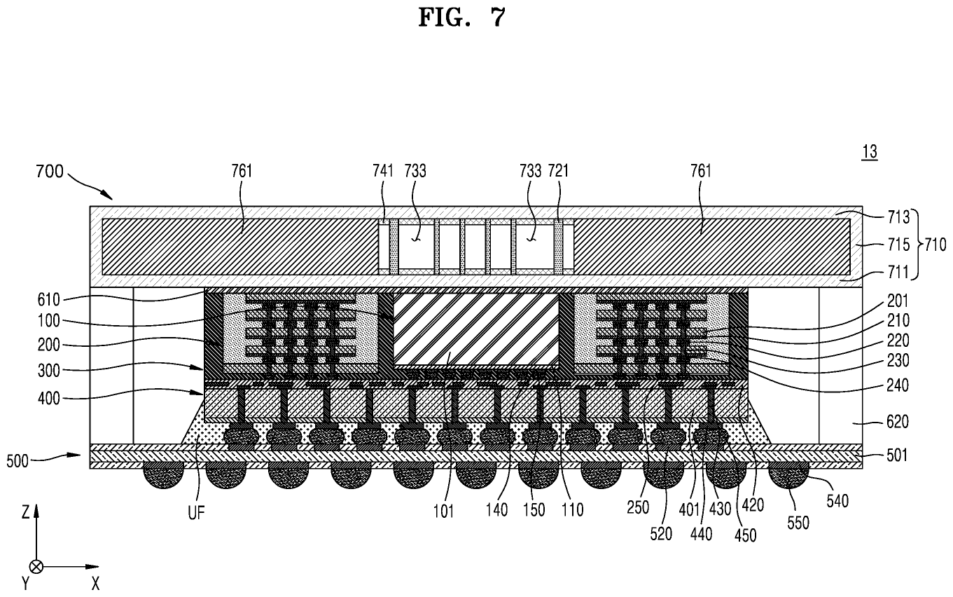

FIG. 6 is a plan layout diagram of a semiconductor package 13 according to an embodiment, and FIG. 7 is a cross-sectional view of the semiconductor package 13 taken along line VII-VII″ in FIG. 6. Hereinafter, the semiconductor package 13 illustrated in FIGS. 6 and 7 is described, focusing on the difference from the semiconductor package 10 described with reference to FIGS. 1 through 3.

Referring to FIGS. 6 and 7, in the semiconductor package 13, a heat dissipation structure 700C may include at least one heat dissipation plate 761 which at least partially covers the second semiconductor device 200. The heat dissipation plate 761 may be thermally combined with the second semiconductor device 200. The heat dissipation plate 761 may be inserted into the heat dissipation chamber 710, and may contact the first isolation walls 721. The heat dissipation plate 761 may be configured to exchange heat with a working fluid in the heat dissipation chamber 710. In some embodiments, the heat dissipation plate 761 may penetrate the lower wall 711, and may contact the thermally conductive adhesive layer 610. In some embodiments, the heat dissipation plate 761 may penetrate the upper wall 713, and be directly exposed to external air. The heat dissipation plate 761 may include or be formed of a metal, such as Cu and Al. In some embodiments, the first semiconductor device 100 having a relatively high heat amount may be cooled initiatively by an immersion cooling method using a working fluid, and the second semiconductor device 200 having a relatively small heat amount may be cooled initiatively by a heat conduction method using the heat dissipation plate 761.

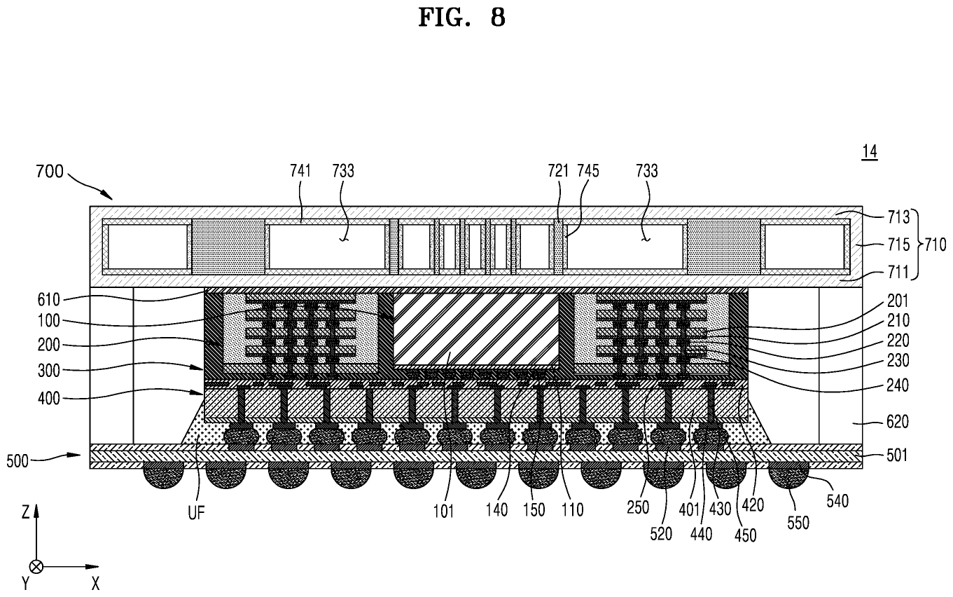

FIG. 8 is a cross-sectional view of a semiconductor package 14 according to an embodiment. Hereinafter, the semiconductor package 14 illustrated in FIG. 8 is described, focusing on the difference from the semiconductor package 10 described with reference to FIGS. 1 through 3.

Referring to FIG. 8, in the semiconductor package 14, a heat dissipation structure 700D may include a second wick structure 745 attached to the surface of the first isolation wall 721. The second wick structure 745 may extend along the surface of the first isolation wall 721. Similar to the first wick structure 741, the second wick structure 745 may generate the capillary force to move the working fluid in a liquidous state toward the heat source, and may include a groove pattern. The material of the second wick structure 745 may be the same as the material of the first wick structure 741.

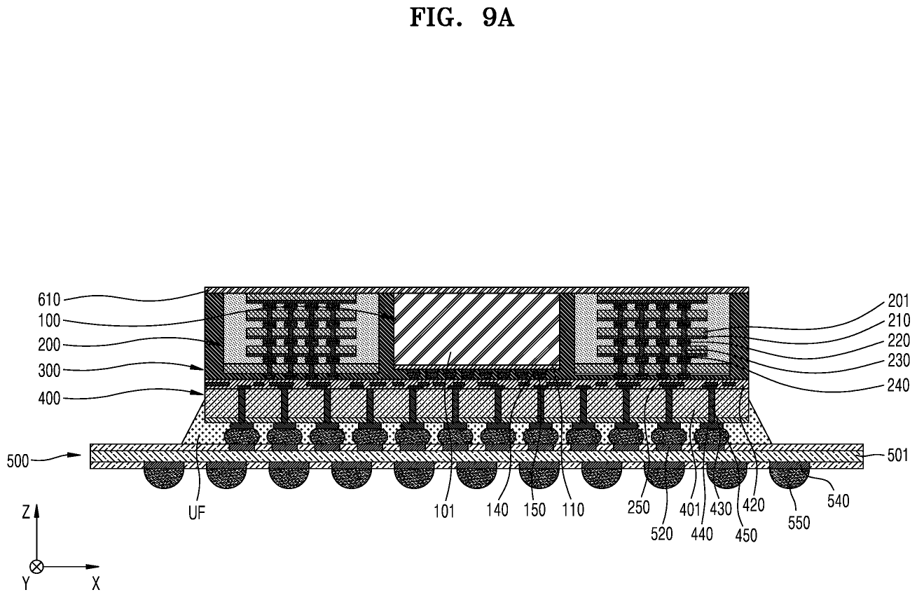

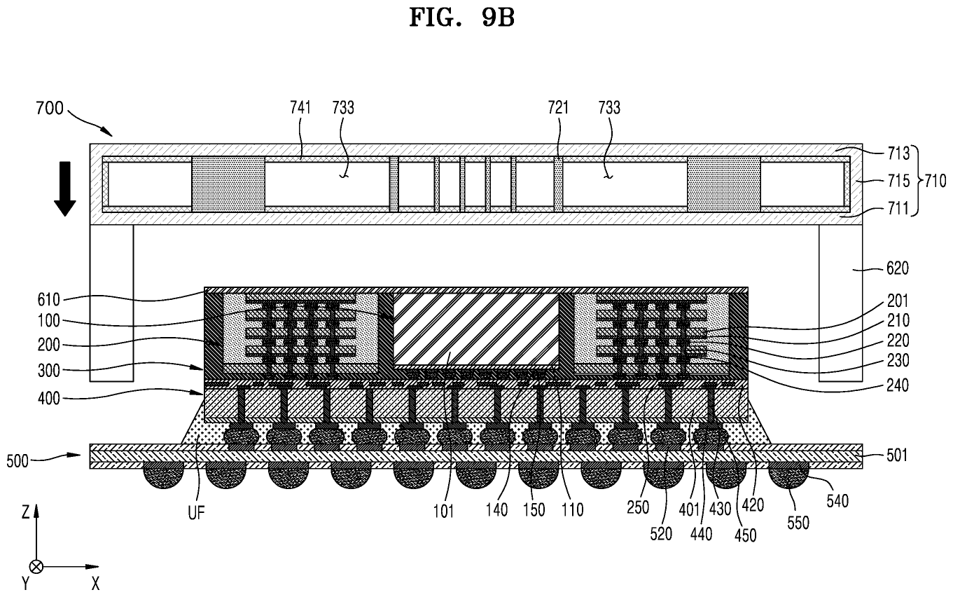

FIGS. 9A and 9B are cross-sectional views illustrating a method of manufacturing the semiconductor package 10, according to some embodiments.

Referring to FIG. 9A, the first and second semiconductor devices 100 and 200 may be mounted on the interposer substrate 400, and the molding layer 300 surrounding the first and second semiconductor devices 100 and 200 may be formed. In operation of forming the molding layer 300, the molding layer 300 may expose the upper surface of the first semiconductor device 100 and the upper surface of the second semiconductor device 200. In some embodiments, the upper surface of the molding layer 300 may be coplanar with the upper surface of the first semiconductor device 100 and the upper surface of the second semiconductor device 200. The interposer substrate 400 may electrically connect the first semiconductor device 100 to the second semiconductor device 200. In addition, the internal connection terminal 450 may be formed under the interposer substrate 400.

Next, the interposer substrate 400, on which the first and second semiconductor devices 100 and 200 are mounted may be arranged above the package substrate 500. The interposer substrate 400 may be arranged above the package substrate 500, so that the internal connection terminal 450 arranged under the interposer substrate 400 is electrically connected to an upper surface of the package substrate 500.

After the interposer substrate 400 is arranged on the package substrate 500, the underfill layer UF may be formed between the interposer substrate 400 and the package substrate 500. The underfill layer UF may be arranged between the interposer substrate 400 and the package substrate 500 to surround the internal connection terminal 450.

Next, the thermally conductive adhesive layer 610 covering the upper surface of the first semiconductor device 100 and the upper surface of the second semiconductor device 200 may be formed. The thermally conductive adhesive layer 610 may conformally cover the upper surface of the first semiconductor device 100 and the second semiconductor device 200, and may further cover the upper surface of the molding layer 300.

Referring to FIGS. 9B and 2, the heat dissipation structure 700 including the support structure 620 may be prepared, and the heat dissipation structure 700 may be attached onto the first and second semiconductor devices 100 and 200. The center portion of the heat dissipation structure 700 may be attached onto the first and second semiconductor devices 100 and 200 by using the thermally conductive adhesive layer 610. In addition, the support structure 620 may be attached to the outer portion of the package substrate 500. For example, the support structure 620 may be attached onto the package substrate 500 by using an adhesive material layer.

As discussed above, a heat sink such as a phase-change heat dissipation cover may be disposed on a top surface of a semiconductor package (e.g., on a top surface of one or more upper-most semiconductor chips of the semiconductor package). The phase-change heat dissipation cover may be a heat dissipation compartment, or a heat dissipation plate that is partly hollow and devoid of solid material, and that includes a liquid formed therein. The phase-change heat dissipation cover may have vertical isolation walls, also described as support walls, formed between a top and bottom surface plate (also described as upper and lower walls), which vertical isolation walls extend in the horizontal direction radially from a center heat dissipation channel, from a plan view, and which may increase in horizontal width in a direction away from the center heat dissipation channel. Radially-arranged heat dissipation channels (e.g., vapor channels as discussed above) in fluid communication with the center heat dissipation channel may also increase in horizontal width in a direction away from the center heat dissipation channel. The liquid may be a refrigerant, such as a liquid that changes phases (e.g., from liquid to gas) within the range of temperatures that the semiconductor chips of the semiconductor package reach during operation. For example, if the liquid is water, it would change phases at 100° C. The liquid may be fully contained within the heat dissipation compartment so that none of the liquid is able to escape to the outside of the phase-change heat dissipation cover. In one embodiment, this is accomplished by using an integrally-formed phase-change heat dissipation cover. One or more solid heat dissipating plates may be formed as part of or within the phase-change heat dissipation cover, in order to additionally dissipate heat. A wicking liner may be used to further enhance the speed and efficiency of heat transfer in the heat dissipation cover.

In testing, using a fluid-filled heat dissipation cover such as described in the various embodiments has been shown to dissipate as much as 10-12 times the amount heat as a conventional non-fluid heat spreader, and to allow semiconductor packages to use between 25% and 200% more power without overheating.

While the inventive concept has been particularly shown and described with reference to embodiments thereof, it will be understood that various changes in form and details may be made therein without departing from the spirit and scope of the following claims.

What is claimed is:

1. A semiconductor package comprising:
a substrate;
a first semiconductor device on the substrate; and
a heat dissipation structure on the first semiconductor device including:
a heat dissipation chamber configured to provide an internal space in which a working fluid moves; and
a plurality of first isolation walls arranged in the heat dissipation chamber to define a first center channel and a plurality of first vapor channels communicating with each other via the first center channel,
wherein:
each of the plurality of first isolation walls vertically overlaps the first semiconductor device,
the first center channel vertically overlaps the first semiconductor device, and
each of the plurality of first vapor channels extends from the first center channel in a lateral direction.

2. The semiconductor package of claim 1, wherein the heat dissipation chamber comprises:
a lower wall attached to the first semiconductor device;
an upper wall on the lower wall; and
sidewalls extending between the lower wall and the upper wall, and
wherein each of the plurality of first isolation walls vertically extends from the lower wall of the heat dissipation chamber to the upper wall of the heat dissipation chamber.

3. The semiconductor package of claim 2, wherein each of the plurality of first isolation walls continuously contacts the lower wall, and extends from the first center channel to a corresponding sidewall thereto of the sidewalls of the heat dissipation chamber.

4. The semiconductor package of claim 3, wherein, in a plan view, a horizontal width of each first isolation wall of the plurality of first isolation walls increases toward the sidewall corresponding thereto among the sidewalls of the heat dissipation chamber.

5. The semiconductor package of claim 1, further comprising a second semiconductor device arranged on the substrate,
wherein:
the heat dissipation structure covers the second semiconductor device,
consumed power of the first semiconductor device is greater than consumed power of the second semiconductor device, and
at least one of the plurality of first isolation walls vertically overlaps both the first semiconductor device and the second semiconductor device.

6. The semiconductor package of claim 5, wherein, in a plan view, at least one of the plurality of first isolation walls extends across the second semiconductor device.

7. The semiconductor package of claim 5, wherein:
the first semiconductor device comprises a logic chip, and
the second semiconductor device comprises a memory chip.

8. The semiconductor package of claim 5, further comprising a third semiconductor device arranged on the substrate,
wherein the heat dissipation structure covers the third semiconductor device, and the heat dissipation structure further comprises a plurality of second isolation walls arranged in the heat dissipation chamber to define a second center channel and a plurality of second vapor channels communicating with each other via the second center channel, and
wherein:
the second center channel vertically overlaps the third semiconductor device,
each of the plurality of second vapor channels extends from the second center channel in a lateral direction,
at least one of the plurality of second isolation walls is connected to at least one of the plurality of first isolation walls, and
at least one of the plurality of first vapor channels communicates with at least one of the plurality of second vapor channels.

9. The semiconductor package of claim 5, wherein the heat dissipation structure further comprises a heat dissipation plate arranged in the heat dissipation chamber and configured to vertically overlap the second semiconductor device.

10. The semiconductor package of claim 1, wherein the heat dissipation structure further comprises a plurality of micro-protruding structures arranged on an external surface of the heat dissipation chamber.

11. The semiconductor package of claim 1, further comprising a first wick structure provided on an internal surface of the heat dissipation chamber and configured to guide a working fluid in a liquid phase.

12. The semiconductor package of claim 11, further comprising a second wick structure provided on a surface of the plurality of first isolation walls and configured to guide a working fluid in a liquid phase.

13. A semiconductor package comprising:
a package substrate;
an interposer substrate on the package substrate;
a plurality of semiconductor devices mounted on the interposer substrate and apart from each other; and
a heat dissipation structure arranged on the plurality of semiconductor devices,
wherein the heat dissipation structure comprises:
a heat dissipation chamber including a lower wall, an upper wall, and sidewalls, and configured to provide an internal space in which a working fluid moves;
a plurality of first isolation walls arranged in the heat dissipation chamber to form a first center channel and a plurality of first vapor channels communicating with each other via the first center channel and extending radially from the first center channel; and
a plurality of micro-protruding structures arranged on an external surface of the heat dissipation chamber,
wherein the first center channel vertically overlaps a first semiconductor device of the plurality of semiconductor devices, and
wherein each of the plurality of first isolation walls continuously extends horizontally from a first end thereof on the first semiconductor device to a second end thereof connected to any one of the sidewalls of the heat dissipation chamber.

14. The semiconductor package of claim 13, wherein each of the plurality of first isolation walls extends from the lower wall to the upper wall of the heat dissipation chamber, and contacts the lower wall and the upper wall of the heat dissipation chamber throughout its horizontal length.

15. The semiconductor package of claim 14, wherein the plurality of semiconductor devices comprise a second semiconductor device apart from the first semiconductor device,
wherein the first semiconductor device comprises a logic chip, and the second semiconductor device comprises a memory chip, and
wherein, in a plan view, at least one of the plurality of first isolation walls extends across the second semiconductor device.

16. A heat dissipation structure comprising:
a heat dissipation chamber including a lower wall in contact with a heat source, an upper wall on the lower wall, and sidewalls extending between the lower wall and the upper wall, and configured to provide an internal space in which a working fluid moves; and
a plurality of first isolation walls extending horizontally and arranged in the heat dissipation chamber to form a first center channel and a plurality of first vapor channels communicating with each other via the first center channel,
wherein the plurality of first vapor channels radially extend from the first center channel.

17. The heat dissipation structure of claim 16, wherein each of the plurality of first isolation walls extends from the lower wall to the upper wall of the heat dissipation chamber, contacts the lower wall and the upper wall of the heat dissipation chamber throughout its horizontal length, and is connected to any one of sidewalls of the heat dissipation chamber.

18. The heat dissipation structure of claim 17, wherein, in a plan view, a width of each first isolation wall of the plurality of first isolation walls increases toward a corresponding sidewall thereto of the sidewalls of the heat dissipation chamber.

19. The heat dissipation structure of claim 17, further comprising a plurality of second isolation walls arranged in the heat dissipation chamber to form a second center channel and a plurality of second vapor channels communicating with each other via the second center channel,
wherein at least one of the plurality of second isolation walls is connected to at least one of the plurality of first isolation walls, and
wherein at least one of the plurality of first vapor channels communicates with at least one of the plurality of second vapor channels.

20. The heat dissipation structure of claim 16, further comprising a plurality of micro-protruding structures arranged on an external surface of the heat dissipation chamber.
